(19) United States
(12) Patent Application Publication
(10) Pub. No.: US 2011/0268235 A1
(43) Pub. Date: Nov. 3, 2011

(54) BORON-10 ENHANCED THERMAL ENERGY

(76) Inventor: Michael Gurin, (US)

(21) Appl. No.: 12/769,650

(22) Filed: Apr. 29, 2010

(51) Int. Cl. G21B 1/00; G21G 4/00; H01L 41/18; C01B 35/02

(52) U.S. Cl. 376/100; 423/249; 252/636; 252/637; 252/62.9 PZ; 252/62.9 R; 977/837

(57) ABSTRACT

The present invention generally relates to high-energy composition utilized with reactors and combustors for generating electricity either directly through nuclear or magnetic energy, or indirectly through thermal energy that incorporate the high-energy composition into at least one reactor operable at a temperature greater than 1000 Celsius and containing the composition with at least one co-reactant of Boron-10, with the Boron-10 specifically enabling an at least five percent increase of energy generation and/or efficiency as compared the same reaction without Boron-10. In one embodiment, the present invention relates to the Boron-10 composition within a high-energy reactor operable at a temperature at least 1000 Celsius and a method that applies at least one externally applied force acting upon the Boron-10 portion of the reactor.

### RELATED APPLICATION DATA

This application does not claim priority to any prior submitted patent pending applications.

### FIELD OF THE INVENTION

The present invention generally relates to high-energy generator composition as utilized within a combustor or a reactor wherein the combustor or reactor contains Boron-10 to enhance the energy generated beyond traditional chemical reactions. In one embodiment, the present invention relates to a reactor containing a Boron-10 composition and a method of increasing reaction temperature and energy by utilizing at least one externally applied field to drive at least one high-energy reaction.

### BACKGROUND OF THE INVENTION

Due to a variety of factors including, but not limited to, global warming issues, fossil fuel availability and environmental impacts, crude oil price and availability issues, alternative energy sources are becoming more popular today. One such source of alternative and/or renewable energy is nuclear energy. One such way to produce nuclear energy is to use fission to convert nuclear energy into a desired thermal energy form, however fission creates radioactive byproducts and is subjected to relatively low temperatures limiting Carnot efficiency. Another such way to produce high-energy states is through traditional combustion reactions, however combustion is limited to relatively low temperatures limiting Carnot efficiency in order to minimize adverse combustion byproducts such as NOx, and SOx. Given this, combustors and reactors that utilize co-reactants that function in efficient manners are desirable.

### SUMMARY OF THE INVENTION

The present invention generally relates to compositions within high-energy reactors, without being bound by theory, that produce low-energy nuclear reactions. In one embodiment, the present invention relates to a Boron-10 composition within a reactor operating at a temperature greater than 1000 degrees Celsius to yield a high-energy state that drives the conversion of nuclear and combustion energy from the co-reactants into electrical energy.

In still another embodiment, the present invention composition is utilized in a method to further increase the resulting total energy produced and to maximize the high-energy states (i.e., minimize the relative level of hot phonons) by an externally applied force exceeding 100 times the force of gravity.

### BRIEF DESCRIPTION OF THE DRAWINGS

FIG. 1 is a cross-sectional illustration of one embodiment of a reactor in accordance with the present invention;

FIG. 2 is a cross-sectional illustration of one embodiment of a reactor in accordance with the present invention; and

FIG. 3 is a cross-sectional illustration of one embodiment of a reactor in accordance with the present invention;

### DETAILED DESCRIPTION OF THE INVENTION

The term “low-energy nuclear reactions”, as used herein, includes any nuclear transmutation or nuclear emission as induced by ultra-low or low momentum neutron absorption.

The term “co-reactant”, as used herein and without being bound by theory, includes any atom, molecule, or composition consumed within a chemical reaction or contributing to the transfer in whole or in part of nuclear energy to the resulting composition of a chemical reaction.

The utilization of the term “Boron-10” as used herein is the inclusion of Boron having a majority of the Boron in the isotope form of Boron-10 (i.e., greater than 50%), as compared to the natural ratio of Boron-10 isotope to other boron isotopes (typically Boron-11).

The term “localized temperature” as used herein is the temperature within 1 micron of the Boron-10 atom, molecule, or composition; principally as compared to the average temperature of the co-reactants or reaction byproducts (which are typically at least 100 degrees Celsius lower than the localized temperature).

The term “alkalide” is defined as a class of ionic compounds where the cations are of the Type I group (Alkali) elements Na, K, Rb, Cs (no known ‘Lithide’ exists). The cation is an alkali cation complexed by a large organic complexant. The resulting chemical form is A+ [Complexant] B−, where the complexant is a Cryptand, Crown Ether, or Aza-Crown.

The term “electride” is defined as being just like alkalides except that the anion is presumed to be simply an electron that is localized to a region of the crystal between the complexed cations.

The term “hot spot”, as used herein is a region having a temperature at least 100 degrees Celsius greater than the average reaction byproducts.

The term “anhydrous” ammonia, as used herein is ammonia with a water content of less than five percent, and preferably less than one percent on a mole ratio.

The term “monatomic”, as used herein is hydrogen or oxygen that occurs as single atoms rather than the usual H2 or O2 seen in hydrogen or oxygen gas respectively. Monatomic atoms have a higher energy state, and quickly combine into their more stable lower energy state.

The term “Brown's Gas”, as used herein is otherwise known as common duct electrolytic oxyhydrogen, such as by WaterTorch Collective, Ltd.

It is understood in the art that Boron-10 captures neutrons as a safety feature within nuclear reactors, but the prior art does not utilize the Boron-10 as a thermal source for an energy generation system. The disclosed invention, without being bound by theory, utilizes Boron-10 for low energy nuclear reactions specifically fusion. A high temperature chemical reaction, such as combustion, occurring at an average temperature greater than 1000 C. produces localized temperatures in excess of 2000 C. The Boron-10, as referenced in this invention, is characterized as a co-reactant. The term co-reactant as used herein is not limited to the traditional sense of a product “consumed” within a reaction, and thus as used within as a catalyst or intermediary in the creation of localized hot spots. In one instance the localized temperature exceeds 3500 Kelvin. In another case, the localized temperature exceeds 10,000 Kelvin. And in another instance, the localized temperature exceeds 20,000 Kelvin. Here, as well as elsewhere in the specification and claims, individual numerical values and/or individual range limits can be combined to form non-disclosed ranges.

The preferred concentration of Boron-10, relative to non-Boron-10 isotopes is greater than 80% (i.e., 4:1). And the particularly preferred concentration of Boron-10 isotopes to other boron isotopes is greater than 90% (i.e., 9:1). The specifically preferred concentration is greater than 95% (i.e., 19:1) Boron-10 isotopes to other boron isotopes.

One embodiment of the Boron-10, as used within the reactor, is in various forms with the preferred forms having a high diffusion barrier of phonons as a method of increasing the localized temperatures. One instance of a diffusion barrier of phonons is known in the art, including a vacuum gap in excess of 10 nm. Another case of a diffusion barrier is thermal barrier coatings as known in the art. One such form of Boron-10 as utilized in the invention is a Boron-10 ceramic, with the ceramic selected as known in the art. A preferred ceramic utilizes predominantly Boron-10 and is prepared from polymeric precursors including h-Boron-10 Nitride and cubic boron nitride as prepared using U.S. Pat. No. 6,153,061. Without being bound by theory, the h-Boron-10 Nitride is a superior insulative and particularly dense material thus minimizing the energy release as a result of a neutron capture being in the form of phonons. Another preferred embodiment utilizes Boron-10 nitride nanotubes, without being bound by theory enhances performance due to polarization and piezoelectricity to provide free electrons and other nuclear emitted particles (e.g., alpha particles).

Yet another embodiment include Boron-10 nitride nanotubes with a Boron-10 nitride/carbon nanotube superlattice. Another embodiment includes Boron-10 compounds such as Boron-10 trifluouride. Without being bound by theory, the lattice structure is supportive of low energy nuclear transmutations.

Yet another embodiment includes electrides as a further method of increasing free electrons. Without being bound by theory, an iron-sulfur cluster has superior electron transfer characteristics to increase the mean free path of the high-energy electron “hot”. One embodiment of a high temperature electride is manganese blue as developed by scientists at Oregon State University in Corvallis including Mas Subramanian. Yet another embodiment of an electride is the combination of sulfur and anhydrous ammonia. A more preferred electride further includes iron at a 1 mole to 1 mole ratio with sulfur. The release of high-energy free electrons increases the nucleus imbalance, and the availability of surface charges to impact the piezoelectric and pyroelectric additions as noted below in the specification. The collection of high surface charges, with a concentration, at points within the lattice structure yield energy concentrating phenomena as seen in sonoluminescence. As known in the art, a condition for blackbody radiation is that the size of the hot spot be greater than the photon matter interaction distance. Thus the concentrated surface charges can create localized temperatures in excess of 10,000 Kelvin (and up to 20,000 Kelvin).

Another embodiment of the invention is the inclusion of Helium-3 or Deuterium within the reactor. A preferred method of including the He-3 and Deuterium is through a porous Boron-10 ceramic, where porous as used herein is sufficient porosity to enable the He-3 or Deuterium to “leak” through the ceramic. A particularly preferred method is such that Boron-10 ceramic is within a hot spot of the reactor, and further at the focal point of an externally applied force. In one instance, the Boron-10 to He-3 or Deuterium mole ratio as present in the reactor (such that the He-3 or Deuterium levels is calculated as operable for the specified flow rate within the reactor) is 2:1. Another case, the Boron-10 to He-3 or Deuterium mole ratio is 10:1. And in yet another case, the Boron-10 to He-3 or Deuterium mole ratio is 1:10.

Yet another embodiment is utilizing liquid gallium, where the liquid gallium surrounds the reactor. The liquid gallium, without being bound by theory, serves as both an electrolyte and an efficient method to capture reaction byproducts including high-energy particles such as any emission from the nucleus including alpha, X-ray, and neutrons. The liquid gallium increases the conversion of the high-energy particles to hot electrons, thus reducing the energy losses being dissipated as phonons. In one instance the liquid gallium surrounds the reactor such that effective thickness of the liquid gallium relative to the exterior of the reactor is at least 20 microns. In another instance the liquid gallium surrounds the reactor such that the effective thickness is 200 microns.

Another embodiment is where the Boron-10 is intercalated in a zeolite. The preferred zeolite is ITQ-4, and the specifically preferred zeolite is further intercalated with cesium such as Cs.sub.x.Si.sub.32.O.sub.64 “CsxSi32O64”, and others where the cesium is either substituted with manganese, thorium, and Boron-10. In one instance, the cesium is intercalated such that x is at least 8. Another instance the cesium is intercalated such that x is at least 2. In yet another case, the cesium is intercalated relative to manganese at a 1:1 mole ratio. Another instance the cesium is intercalated relative to Boron-10 between a 1:1 and a 4:1 mole ratio. And another instance thorium is intercalated relative to Boron-10 between a 1:2 and a 5:1 mole ratio.

Yet another embodiment is the Boron-10 combined with thorium as a fluoride salt of thorium. The particularly preferred thorium salt is thorium boride (from Boron-10), and particularly preferred having particle size less than 50 nm. The resulting thorium salt can be combined with anhydrous ammonia, without being bound by theory, to create solvated electrons. Another embodiment is a nanoscale thorium (having a particle size less than 50 nm), in reduced state, in which thorium is mixed with monatomic oxygen within the reactor. Particularly a combination of tungsten and thorium are mixed, preferably with thorium to tungsten on a mole to mole basis is between 100:1 and 10:1 and specifically preferred at 30:1. In one instance the Boron-10 to thorium ratio is between a 1:2 and a 5:1 mole ratio.

In yet another embodiment, the Boron-10 is combined with lithium. A preferred form of lithium is at least one of a lithium hydrogen matrix, lithium niobate, and lithium glycine carbonate. And a particularly preferred form of lithium is in the isotope form of lithium-6. In one instance the Boron-10 to lithium mole ratio is between a 5:1 ratio and a 1:1 ratio, such that the lithium is calculated on the basis of operable mass flow rate and instantaneous levels of lithium within the reactor.

Another embodiment, the Boron-10 has a particle size of less than 100 nm, and preferably less than 20 nm, is combined with ethyl ammonium nitrate “EAN”. The particularly preferred embodiment further combines monatomic oxygen within the reactor. Without being bound by theory, the EAN limits the premature oxidation of boron-10 powder, and the high energetic reaction enables the potential fusion of the captured neutron with the close proximity hydrogen within the EAN. In one instance the Boron-10 to EAN on a volume basis is between 1:2 and 1:10.

Yet another embodiment includes nanocrystals of piezoelectric materials. Particularly preferred piezoelectric materials include zinc oxide, barium titanate, and strontium titanate. Another embodiment includes nanocrystals of pnictides. Pnictides, as recognized in the art are materials based on iron and arsenide. An embodiment also includes nanocrystals of pyroelectric crystals, with preferred piezoelectric crystals including triglycine sulfate (NH₂CH₂COOH)₃.H₂S0₄, “TGS” or lithium tantalite. The TGS is particularly preferred due to the sulfur contribution in electrides, without being bound by theory, and enhancing free electrons. The combination of Boron-10 and glycine is desirable, as glycine has closely bound hydrogens. Yet another embodiment is Boron-10 combined with deuterium, where the Boron-10 is preferred in a Boron-10 glycine carbonate form. A further combination with strontium barium niobate is specifically preferred. Without being bound by theory, the addition of piezoelectric, pnictides, and pyroelectric increases the free electron or surface charge to levels in excess of traditional hot phonon energy states. In one instance, the mole ratio of Boron-10 to piezoelectric, pyroelectric, or pnictides is between 1:1 and 1:5. In another instance, the mole ratio of Boron-10 to piezoelectric, pyroelectric, or pnictides is between 1:10 and 1:20.

Another embodiment utilizes any of the above Boron-10 products, combinations thereof, by encompassing the reactor thermal energy as directly converted to electricity using an electromagnetic heat engine with magnetization and demagnetization frequency of greater than 100 Hertz. Electromagnetic heat engine as known in the art enables the high energetic states to be captured by the electromagnetic field prior to diffusing as hot phonons. In one instance the frequency is 10 kilohertz. Another case the frequency is 10 megahertz. And another case the frequency is in excess of 1 gigahertz. The fundamental objective, without being bound by theory, is for the frequency of the electromagnetic magnetization and demagnetization to be greater than the time required for the hot phonons to relax or diffuse such that the high-energy state realized from capturing a neutron by Boron-10 is converted into magnetic energy preferably over thermal energy.

Virtually all embodiments of the invention benefit from having more tightly bound hydrogen prior to entering the reactor, with the Boron-10 bound in a hydrogen matrix for example ammonia borane, polyborazylene, and boron hydride. In these examples when hydrogen is bound to Boron-10, the addition of monatomic oxygen within the reactor yields a very high energetic state where neutrons are absorbed by the Boron-10 and the imbalance of protons, neutrons, and free electrons is within very close proximity to the hydrogen. When Boron-10 is not within a hydrogen matrix, the combination of monatomic hydrogen provides a higher energy state as compared to H2. Yet another form of monatomic hydrogen is present in the particularly preferred Brown's Gas. The combination of tightly bound hydrogen and externally applied forces extends the period of time in which the hydrogen remains within close proximity to the Boron-10, without being bound by theory, increases the probability of the neutron capture within the Boron-10 leading to a fusion event. In one instance, the Boron-10 to hydrogen mole ratio is between 1:5 and 1:50. Without being bound by theory, it is preferable that the hydrogen nucleus is within 10 nanometers of the Boron-10 nucleus.

One such method to increase the localized energy is to include Boron cermets such as boron carbide-copper cermet. The preferred utilization of boron cermets is to surround the reactor. Without being bound by theory, the doping of Boron cermets with silicon (Si) and/or germanium (Ge) improves the thermoelectric properties. The cermet can be replaced with pyrolytic hexagonal boron nitride. The boron that surrounds the reactor is less particularly Boron-10, as compared to the use of boron within the reactor. Yet another boron compound to surround the reactor is pyrolytic hexagonal boron nitride.

One of the critical features of the disclosed invention is to minimize the distance between a captured neutron and a candidate material for absorption from the now nuclear imbalanced nucleus. Numerous methods are utilized either individually or in combination. Superior results are achieved by utilizing a stronger force in a more concentrated area, particularly with the reactor area having a higher concentration of Boron-10 atoms. One embodiment of the externally applied force within the reactor has is greater than 100 times the force of gravity. The more preferred embodiment has an applied external force of greater than 1000 times the force of gravity. The particularly preferred embodiment has an applied external force of greater than 100,000 times the force of gravity. And the specifically preferred embodiment within the reactor has an applied external force of greater than 1,000,000 times the force of gravity. The externally applied force is from any individual or jointly applied force including electromagnetic, centrifugal, and acoustic force. The particularly preferred acoustic force creates a standing wave within the reactor, and specifically preferred such that the standing wave resonates within the Boron-10 composition.

In yet another embodiment, the combination of any of the above compounds/materials is anticipated within the reactor. One such example is the inclusion of electrides within the reactor and monatomic hydrogen. Another such example is the inclusion of sulfur, anhydrous ammonia, within the reactor and monatomic oxygen. Further, it is preferred such that the most energetic reactants are combined within the focal point of an externally applied force.

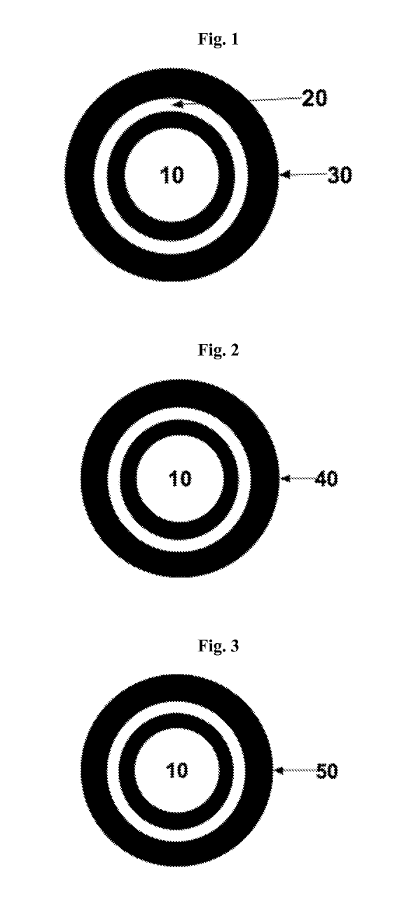

Exemplary embodiments of the present invention will now be discussed with reference to the attached Figures. Such embodiments are merely exemplary in nature and not to be construed as limiting the scope of the present invention in any manner. With regard to FIGS. 1 through 10, like reference numerals refer to like parts.

Turning to FIG. 1, is the reactor 10 (shown as cavity) as surrounded by Boron-10 cermet 20 and then ultimately surrounded by the externally applied force 30. The Boron-10 cermet serves in this capacity as a material to capture stray neutrons moving from the reactor to outside of the core reactor zone. The externally applied force focal point is within the reactor as depicted.

Turning to FIG. 2, the reactor 10 is now surrounded by the electromagnetic heat engine 40. The electromagnetic heat engine has the externally applied force focal point within the reactor.

Turning to FIG. 3, the reactor 10 is now surrounded by a generator of externally applied force 50.

Although the invention has been described in detail with particular reference to certain embodiments detailed herein, other embodiments can achieve the same results. Variations and modifications of the present invention will be obvious to those skilled in the art and the present invention is intended to cover in the appended claims all such modifications and equivalents.

What is claimed is:

1. A high-energy generator composition comprised of at least one co-reactant comprised of Boron-10 operable in a reactor having at least one reaction area with a temperature greater than 1000 degrees Celsius and the Boron-10 composition increases the energy produced by the reaction by at least five percent over the same reaction without the Boron-10 as a co-reactant.

2. The high-energy generator composition according to claim 1 with the at least one co-reactant comprised of Boron-10 being a Boron-10 ceramic.

3. The high-energy generator composition according to claim 2 whereas the Boron-10 ceramic is prepared from polymeric precursors including h-Boron-10 Nitride and cubic boron nitride.

4. The high-energy generator composition according to claim 2 whereas the Boron-10 ceramic is prepared as boron nitride nanotubes including boron nitride nanotubes having a boron nitride/carbon nanotube superlattice.

5. The high-energy generator composition according to claim with the at least one co-reactant comprised of Boron-10 selected from the group of Boron-10 compounds including Boron-10 trifluouride.

6. The high-energy generator composition according to claim 1 further comprised of electrides.

7. The high-energy generator composition according to claim 1 further comprised of iron-sulfur clusters.

8. The high-energy generator composition according to claim 1 further comprised of at least one of manganese blue, Helium-3, and Deuterium.

9. The high-energy generator composition according to claim 1 further comprised of liquid gallium where as the liquid gallium is an electrolyte.

10. The high-energy generator composition according to claim 1 further comprised of at least one of sulfur, and anhydrous ammonia.

11. The high-energy generator composition according to claim 10 wherein the sulfur is an iron-sulfur cluster.

12. The high-energy generator composition according to claim 11 further comprised of at least one of Helium-3 and Manganese blue.

13. The high-energy generator composition according to claim 1, wherein the Boron-10 is intercalated in a zeolite.

14. The high-energy generator composition according to claim 12, wherein the zeolite is ITQ-4.

15. The high-energy generator composition according to claim 1 wherein the Boron-10 is further comprised of at least one of cesium, manganese, and thorium.

16. The high-energy generator composition according to claim 15, wherein the thorium is a liquid fluoride salt of thorium.

17. The high-energy generator composition according to claim 16, wherein the liquid fluoride salt of thorium is dissolved in ammonia.

18. The high-energy generator composition according to claim 1, wherein the Boron-10 is further comprised of lithium.

19. The high-energy generator composition according to claim 18, wherein the lithium is at least one of a lithium hydrogen matrix, lithium niobate, and lithium glycine carbonate.

20. The high-energy generator composition according to claim 1, wherein the Boron-10 has a particle size less than 100 nm and is further comprised of ethyl ammonium nitrate.

21. The high-energy generator composition according to claim 1, wherein the Boron-10 is further comprised of nanocrystals of piezoelectric materials including zinc oxide, barium titanate, and strontium titanate.

22. The high-energy generator composition according to claim 1, wherein the Boron-10 is further comprised of nanocrystals of pnictides.

23. The high-energy generator composition according to claim 1, wherein the Boron-10 is further comprised of nanocrystals of pyroelectric crystals including triglycine sulfate or lithium tantalite.

24. The high-energy generator composition according to claim 1, wherein the Boron-10 is further comprised of at least one of deuterium, Boron-10 glycine carbonate, and strontium barium niobate.

25. A method of using the high-energy generator composition according to claim 1, wherein the resulting energy is converted to electricity using an electromagnetic heat engine with magnetization and demagnetization frequency of greater than 10,000 Hertz.

26. The high-energy generator composition according to claim 26, wherein the Boron-10 is further comprised of at least one of pyroelectric, piezoelectric, or pnictide crystals.

27. The high-energy generator composition according to claim 1, wherein the Boron-10 is in a hydrogen matrix including ammonia borane, polyborazylene, and boron hydride.

28. The high-energy generator composition according to claim 1, wherein the Boron-10 is further comprised of monatomic oxygen.

29. The high-energy generator composition according to claim 1, wherein the Boron-10 is further comprised of monatomic hydrogen.

30. The high-energy generator composition according to claim 1, wherein the Boron-10 is further comprised of Brown's Gas.

31. The high-energy generator composition according to claim 1 further comprised of boron cermets including boron carbide-copper cermet wherein the boron cermet surrounds the reactor.

32. The high-energy generator composition according to claim 31 wherein the boron cermet is doped with at least one of silicon and germanium.

33. The high-energy generator composition according to claim 1 further comprised of pyrolytic hexagonal boron nitride wherein the pyrolytic hexagonal boron nitride surrounds the reactor.

34. A method of using the high-energy generator composition according to claim 1, wherein the reactor has an applied external force of greater than 100 times the force of gravity.

35. A method of using the high-energy generator composition according to claim 1, wherein the reactor has an applied external force of greater than 1000 times the force of gravity.

36. A method of using the high-energy generator composition according to claim 1, wherein the reactor has an applied external force of greater than 100,000 times the force of gravity.

37. A method of using the high-energy generator composition according to claim 1, wherein the reactor has an applied external force of greater than 1,000,000 times the force of gravity.

38. A method of using the high-energy generator composition according to claim 34, wherein the applied external force is from at least one of electromagnetic, centrifugal, and acoustic force.
